(19) United States
(12) Patent Application Publication
(10) Pub. No.: US 2003/0218259 A1
(43) Pub. Date: Nov. 27, 2003

(54) Bond pad support structure for a semiconductor device

(76) Inventors: Daniel Patrick Chesire, Orlando, FL (US); Gerard Zaneski, Orlando, FL (US); Mary Drummond Roby, Orlando, FL (US); Daniel Joseph Vitkavage, Winter Garden, FL (US); Scott Jessen, Orlando, FL (US)

Correspondence Address: BEUSSE, BROWNLEE, BOWDOIN & WOLTER, P. A., 390 NORTH ORANGE AVENUE, SUITE 2500, ORLANDO, FL, 32801, US

(21) Appl. No.: 10/153,163

(22) Filed: May 21, 2002

(51) Int. Cl. H01L 23/053; H01L 23/12; H01L 23/48; H01L 23/52; H01L 29/40

(52) U.S. Cl. 257/786; 257/758; 257/700; 257/701

(57) ABSTRACT

A bond pad support structure for a semiconductor device comprises at least two metal layers subjacent an uppermost passivation layer on the device. An opening through the passivation layer exposes a top surface of a top metal layer. A metal feature is formed in an insulating layer, disposed between the two metal layers, and divides the insulating layer into a plurality of discrete sections. The metal feature includes a plurality of intersecting metal-filled recesses that interconnect the two metal layers. At least a portion of the metal feature is disposed within a cross-sectional area defined as a perimeter of a periphery of the opening.

### BACKGROUND OF THE INVENTION

The present invention relates generally to the fabrication of semiconductor integrated circuit devices, and more particularly, to bond pads on semiconductor devices and support structures for bonding or solder bump pads.

Integrated circuit devices are typically formed by metallization layers separated by dielectric layers. External connections to the devices are made via bond sites at the highest metallization layer. A bond site or bond pad on an integrated circuit typically includes at least one metal element formed within the top metallization layer. An uppermost passivation layer is formed over the metal layer, and covers the entire device. A window is formed within the passivation layer, exposing a top surface of the bond site. The bond site is then used to electrically connect the device to an external system.

Following the fabrication of the semiconductor devices on a wafer, each device, also known as chips or die, is tested for functionality, or the wafers are “sorted”. Typically, a wafer having devices fabricated thereon is placed on a test system. Electrical probes from a tester contact bond pads formed on each of the devices to determine if individual devices meet specifications.

After the wafers are sorted, the wafer is cut or singulated and the devices are separated from one another using cutting tools known to those skilled in the art. The devices are then assembled into a “package component” or other chip carrier module using procedures known as die attach or die bonding. The devices are typically mounted on a lead frame (ceramic or organic substrate depending on end use), fixed into a module with other chips or connected directly onto a printed-circuit board.

Subsequent to the attachment of the devices to package substrates, electrical connections are made between the bond pads on the devices and the electrical leads on the package. The electrical connections are made using different techniques including wire bonding, flip-chip bonding and tape-automated bonding. At least with respect to wire bonding and flip-chip bonding, a bond pad is subjected to a force applied directly to the bond that may damage underlying layers, materials, or components of a device.

In wire bonding techniques, such as thermo-compression, ultra-sonic and thermo-sonic bonding, a metal lead wire is pressed against a bond pad. Depending on the particular technique, the wire and device are heated and/or subjected to ultra-sonic vibrations to bond the metal wire to the bond pad of the semiconductor device.

The devices are subjected to thermal and mechanical stresses during these procedures. The device layers underlying the bond pad are compressed and in some instances materials or components may be cracked and damaged. Cracks in the dielectrics may propagate through the layers to device components, which may be damaged. This cracking may promote shorting of devices, and components fabricated underneath the bond pad may be damaged directly from the force of the compression. This same problem exists for other bonding techniques such as flip-chip bonding, which technique is well known to those skilled in the art. In addition, damage to the device may be similarly caused during wafer sorting, when the testing probes are pressed against the bond pad.

Substructures have been integrated into a semiconductor device and bond pad to minimize the amount of damage caused by wire bonding and probing. U.S. Pat. No. 6,306,749, issued to Lin, and U.S. Pat. No. 6,313,541, issued to Chan, et al. each disclose substructures that are formed in a device along an edge of the bond pad and subjacent a top layer of the device. These substructures extend outwardly from the bond pad edge and interconnect with a lower device layer. These substructures primarily prevent the bond pad from peeling off due to mechanical and/or thermal stress to the bond pad and underlying layers, and inhibit cracking in lower device layers beyond a perimeter of the bond pad.

Similarly, U.S. Pat. No. 5,248,903, issued to Heim, discloses a process intended to prevent propagation of dielectric cracking. The Heim patent discloses a “composite bond pad” including two spaced apart pad elements and an insulating layer disposed between the pad elements. Openings, in the form of trenches or vias, are disposed along a peripheral region of a lower pad element. The openings are filled with a conductive metal such as tungsten and interconnect the bond pad elements.

The above-described prior art systems are not believed to prevent damage to device components located directly beneath bond sites but rather are limited to confining propagation of cracks beyond a perimeter of the bond site. Efforts to prevent component damage include using bond pad support structures integrated in devices subjacent the bond pad. For example, via plugs have been incorporated into an interconnect structure to support a bond pad. The via plugs interconnect two metal layers including a top metal layer that serves as the bond pad. The via plugs provide additional support to the bond pad, and to some degree protect underlying components. However, cracks in the dielectric between the metal layers can extend between the via plugs and potentially damage intra-level device components. Similarly, those devices that integrate anchoring techniques subjacent to the bond pad, and as shown in U.S. Pat. No. 5,962,919 issued to Liang, et al., and U.S. Pat. No. 5,707,894 issued to Hsiao, may not effectively isolate damage to an underlying dielectric.

Thus, a need exists to provide a bond pad and a support structure that effectively protects device components that are disposed within the device under the bond pad, isolate any damage within an underlying layer to an area subjacent the bond pad, and inhibits bond pad peeling that may result from underlying layer damage.

### SUMMARY OF THE INVENTION

The above and other disadvantages of the prior art are addressed by a bond pad support structure according to the present invention. A semiconductor device includes at least one bond pad for testing the functionality of the device and/or for electrically connecting the device to a device package. The bond pad and its support structure include at least two metal layers and an insulating layer interposed between the two metal layers. Each of the metal layers includes a metal pad element. A metal feature extending within the insulating layer interconnects the two metal pads. The feature is patterned in such a manner to divide the insulating layer into a plurality of sections, at least a portion of which are disposed within a cross-sectional area of the device defined by a periphery of a bond pad opening. In a preferred embodiment, the feature includes an array of metal-filled recesses, which are arranged to intersect one another, forming a plurality of discrete dielectric sections.

The bond pad support structure is not limited to two interconnected metal layers, but may include two or more metal layers. For example, in a device having seven metal layers, the top three metal layers (M1, M2 and M3) may be interconnected through metal-filled recesses. A first metal feature interconnects layers M1 and M2, and a second metal feature interconnects layers M2 and M3.

In this manner, the metal features in combination with the metal elements provide a strong composite interconnect structure that distributes the stress and/or force applied during device testing and wire bonding. The support structure minimizes the amount of damage occurring to device components subjacent to the bond pad. In addition, the isolation of the dielectric sections inhibits propagation of cracking, and ideally confines cracks within a periphery of the array of the metal-filled recesses. The interconnection of the metal layers provides the added benefit of preventing bond pad peeling that may occur during electrical test probing and wire bonding.

### BRIEF DESCRIPTION OF THE DRAWINGS

Some advantages of the present invention having been stated, others will appear as the description proceeds, when considered in conjunction with the accompanying drawings, which are not necessarily drawn to scale, in which:

FIG. 1 is a perspective view of a semiconductor device.

FIG. 2 is a partial sectional view of a semiconductor device illustrating a bond pad and support structure.

FIG. 3 is a top sectional view taken along line 3-3 in FIG. 2.

### DETAILED DESCRIPTION OF THE DRAWINGS

Semiconductor device 11, as shown in FIG. 1, typically includes a plurality of metallization layers that are separated by insulating dielectric layers fabricated over a wafer substrate. The metallization layers have electrical components such as diodes, transistors, capacitors, and resistors formed therein. Vias, holes or trenches, formed within insulating layers are filled with conductive metals to electrically interconnect components of the metallization layers and provide mechanical support.

A semiconductor device such as device 11 generally includes a passivation layer 13, usually comprising a dielectric material, overlaying the underlying composite stack of metallization layers, insulating layers and wafer substrate, generally designated as 25. Typically, a passivation layer is approximately 10,000 Å thick. Openings are etched in the passivation layer 13, exposing discrete areas of a top metallization layer, forming what are known as bond pads 12. These bond pads 12 serve as connections from the device circuitry to a device package (not shown). Wire bonds 24, solder bumps or tape-automated bonding may be formed on the bond pads 12, for connection to the package substrate (not shown).

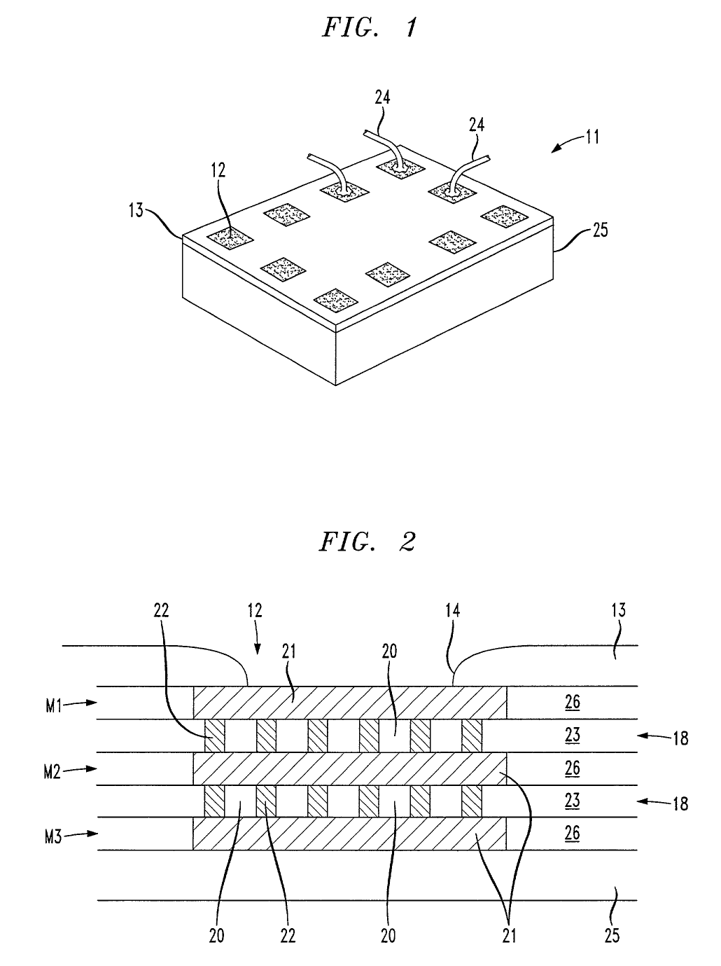

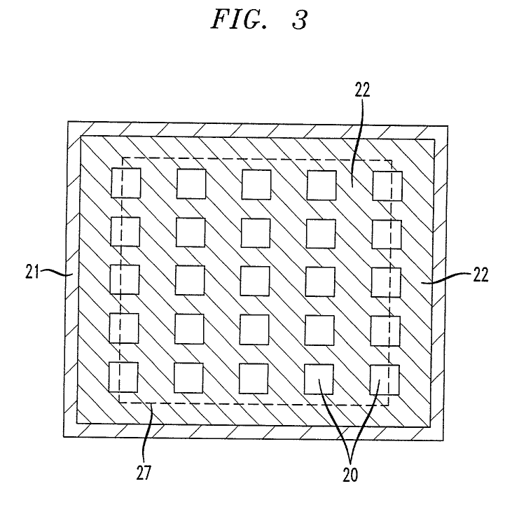

With respect to FIG. 2, one form of the present invention for a bond pad and support structure therefore is illustrated. In the embodiment shown in FIG. 2, the bond pad support structure interconnects three metal layers. Semiconductor devices may have as many as nine or more metal layers and the bond pad and support structure therefore may be integrated in an uppermost plurality of metal layers. Reference is made to those upper layers integrated with the bond pad. The passivation layer 13 overlays the top metal layer M1 of the device. The top metal layer M1 includes a metal pad element 21 formed within a non-conductive material 26. The next two lower metal layers are respectively identified as M2 and M3. An opening 14 etched in the passivation layer 13 exposes a discrete area of the top surface of the pad element 21, forming the bond pad 12.

The two lower metal layers M2 and M3 underlying the top metal layer M1 form part of a support structure for the bond pad 12. Each of the metal layers M2 and M3 include a metal pad 21 circumscribed by non-conductive material 26. The metal layers M1, M2 and M3 may be fabricated using processes known to those skilled in the art. For example, damascene processes may be used to fabricate the metal layers when copper is used as the conductive metal. Alternatively, a subtractive etch process is typically used to fabricate aluminum metal layers. The non-conductive material 26 may include dielectrics such as silicondioxide, silicon nitride or other nonconductive materials such as polyamides, polysilicides or PCBs.

Insulating layers 18 are interposed between the top metal layer M1 and lower metal layer M2, and between the lower metal layers M2 and M3. The insulating layer 18 includes nonconductive material 23 which may typically comprise a dielectric material having a known dielectric constant. A plurality of holes, or vias or trenches are etched into the dielectric material 23 and then filled with a conductive metal. The patterned features divide or separate the insulating layer into a plurality of sections. In an advantageous embodiment, a plurality of metal-filled recesses 22 are formed within the dielectric material 23. These metal filled recesses 22 may be constructed using damascene processes, by which recesses are etched in the dielectric material 23. A conductive metal is then deposited within the recesses 22. The conductive metals may include any number of metals typically used for fabrication in interconnect structures such as refractory metals like tungsten, titanium, tantalum, cobalt or alloys thereof including titanium nitride and tantalum nitride. As known to those skilled in the art, a contact layer is first formed within the recesses 22, and then a conductive metal is deposited over the contact layer. The insulating layer 18 is then planarized using chemical-mechanical polishing techniques to remove excess metal outside the recesses 22 and planarize the device. Other techniques, such as subtractive etching techniques may be used to form the metal feature. The present invention is not limited by the damascene process, or the metal deposition process disclosed herein.

A metal layer (M1, M2 or M3) is then fabricated over an insulating layer as described above. If copper is used to fill the recesses in the insulating layer 18, consecutive insulating layers 18 and metal layers (M1, M2 or M3) may be fabricated using a dual damascene process.

In this manner, the metal-filled recesses 22 provide an electrical and mechanical interconnection between the respective metal layers M1, M2 and M3. The dimensions of the metal sites, the different device layers and recesses will vary according to the geometry of the component devices, as well as the type of metals and dielectric materials of a semiconductor device. Additional, or fewer, metal layers may be connected together in this method to provide the required device protection.

In an advantageous embodiment of the present invention, aluminum metal contact pads are fabricated in a device containing seven metal layers for a 0.14 μm gate size of a transistor component device. The metal pad elements 21 typically have dimensions similar to one another. For example, rectangular aluminum metal pads may be about 56 μm×64 μm, with a pad pitch of about 60 μm, or a 4 μm spacing between the metal pads 21 on respective metal layers M1, M2 and M3. The metal layers M1, M2 and M3, may be about 8,000 Å thick; however, metal layers may be as thick or thin as necessary to fulfill the device design functions. The opening 14 etched through the passivation layer 13 has a periphery that extends within a cross-sectional area defined by a periphery of the top metal pad element 21. In an advantageous embodiment, the top metal pad element 21 extends about 2 μm beyond a periphery of the opening 14. For example, with respect to the specific dimensions for the metal pad element 21 referenced above, the opening 14 may be about 52 μm×60 μm.

As mentioned above, the insulating layers 23 typically comprise a nonconductive material such as a dielectric material. The thickness of the insulating layer 23 will vary, in part, according to the type of dielectric layers used, and the type of interconnect features formed within the dielectric. In an advantageous embodiment, in which the device includes a 0.14 μm device gate size with aluminum metal pad elements 21, the insulating layer 23 comprises a dielectric material having a dielectric constant of between about 3.0 to about 3.5 and approximately 8000 Å thick.

Similarly, the size and spacing of the recesses 22 will depend in part on the type of nonconductive material used to fabricate the insulating layer 23. In an advantageous embodiment in which the insulating layer 23 comprises a dielectric constant of about 3.0 to about 3.5, and the conductive metal used to fill the recess 22 is a refractory metal or refractory metal alloy, the recesses may range from about 0.24 μm to about 0.48 μm in width, and are spaced about 1.25 μm to about 2.06 μm apart. One skilled in the art will appreciate that the size and spacing may vary depending on various factors and limitations as referred to above.

In a preferred embodiment, the recesses are arranged in a grid-like arrangement as shown in FIG. 3, in which the metal-filled recesses intersect one another dividing the dielectric material 23 into a plurality of discrete sections 20. In the embodiment illustrated in FIG. 3, the metal-filled recesses 22 extend either parallel or perpendicular to one another forming a grid-like formation; however, the invention is not limited to the specific arrangement shown in FIG. 3, but may include other arrangements that form discrete sections 20. For example, the metal-filled recesses may intersect one another at varying angles other than perpendicular to one another. The dashed line 27 represents a periphery defined by the opening 14 in the passivation layer 13. The recesses 22 are disposed within a peripheral edge of the metal pad element 21.

While the preferred embodiments of the present invention have been shown and described herein in the present context, it will be obvious that such embodiments are provided by way of example only and not of limitation. Numerous variations, changes and substitutions will occur to those of skilled in the art without departing from the invention herein. For example, the present invention need not be limited to best mode disclosed herein, since other applications can equally benefit from the teachings of the present invention. Accordingly, it is intended that the invention be limited only by the spirit and scope of the appended claims.

We claim as our invention:

1. A semiconductor contact structure, comprising:
(a) a first metal layer;
(b) an insulating material overlaying the first metal layer;
(c) a second metal layer disposed over the insulating material and aligned with respect to the first metal layer;
(d) a window extending through a passivation layer overlaying said second metal layer and exposing a top surface of the second metal layer; and
(e) a metal feature formed disposed between the first metal layer and said second metal layer, said metal feature separating the insulating material into a plurality of discrete sections.

2. The contact structure of claim 1 wherein at least a portion of the metal feature is disposed within a cross-sectional area defined by a periphery of said window.

3. The contact structure of claim 1 wherein said metal feature comprises at least one elongated metal-filled recess surrounding a plurality of metal-filled recesses, and said plurality of sections are disposed within said elongated recess.

4. The contact structure of claim 1 wherein said metal feature comprises a first plurality of metal-filled recesses extending parallel to one another, and a second plurality of metal-filled recesses wherein the recesses extend parallel to one another and intersect said first plurality of metal-filled recesses.

5. The contact structure of claim 1 and including a third metal layer below said second metal layer and spaced therefrom by an insulating layer having another metal feature formed therein for supporting said second metal layer.

6. The contact structure of claim 4 wherein said second plurality of recesses are arranged substantially perpendicular to the first plurality of recesses.

7. A support structure for a bond pad formed on a semiconductor device, comprising:
(a) a top metal pad element;
(b) another metal pad element below said top metal pad element;
(c) an insulating material layer between said top metal pad element and said another metal pad element; and
(d) a metal feature disposed between aid metal pad elements and separating the insulating material into a plurality of discrete sections.

8. The support structure of claim 7 further comprising a third metal pad element spaced below said another metal pad element and spaced therefrom by another insulating material layer, said another insulating material layer including the metal feature separating the another insulating material layer into a plurality of discrete sections.

9. The support structure of claim 8 wherein each said metal feature comprises a grid of metal-filled recesses in each said insulating material layer, said metal features abutting each adjacent metal pad element.

10. The bond pad support structure of claim 8 wherein said metal feature comprises at least one metal-filled elongated recess surrounding a plurality of metal-filled recesses, said plurality of sections being disposed within said elongated metal-filled recess.

11. The support structure of claim 7 wherein said bond pad comprises a first metal pad element subjacent an uppermost passivation layer, an opening formed in said passivation layer exposing a top surface of the first metal pad element, said metal feature being disposed at least within an area defined by said opening.

12. A method for the fabrication of a semiconductor device, comprising the steps of:
(a) forming at least two metal layers over a device substrate, including a top metal pad element having a bonding site on a top surface thereof, and a lower metal pad element positioned below said metal pad elements;
(b) forming an insulating layer interposed between the metal pad elements; and,
(c) interconnecting the metal pad elements with a metal feature, and said metal feature separating the insulating layer into a plurality of discrete sections.

13. The method of claim 12 wherein said interconnecting step comprises patterning the metal feature in the insulating layer, etching recesses within the insulating layer in accordance with the patterned metal feature, filling the recesses with a conductive metal and subsequently forming the top metal pad element over the insulating layer.
